(19) United States
(12) Patent Application Publication
(10) Pub. No.: US 2010/0128212 A1
(43) Pub. Date: May 27, 2010

(54) MANUFACTURING APPARATUS FOR ORIENTED FILM, MANUFACTURING METHOD FOR ORIENTED FILM, LIQUID CRYSTAL DEVICE, AND ELECTRONIC DEVICE

(75) Inventors: Hideo NAKATA, Suwa (JP); Takuya MIYAKAWA, Okaya (JP); Norio OKUYAMA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/689,403

(22) Filed: Jan. 19, 2010

Related U.S. Application Data
(62) Division of application No. 11/485,551, filed on Jul. 12, 2006.

(30) Foreign Application Priority Data
Jul. 14, 2005 (JP) 2005-205470

(51) Int. Cl. G02F 1/1337; C23C 14/34

(52) U.S. Cl. 349/124; 204/192.15

(57) ABSTRACT

A manufacturing apparatus for manufacturing an oriented film of a liquid crystal device holding a liquid crystal between a pair of substrates facing each other, comprising: a film formation chamber; an evaporation section having an evaporation source, evaporating an oriented film material on the substrate by a physical vapor deposition, and forming the oriented film in the film formation chamber; a shielding plate arranged between the evaporation section and the substrate, having an elongated opening for selectively evaporating the oriented film material, and covering an area of the substrate on which the oriented film is not formed; and a first regulating member arranged between the evaporation source and the shielding plate and at a position closer to the evaporation source than from the shielding plate, regulating a sublimating direction in which the oriented film material is sublimated.

### CROSS-REFERENCE TO RELATED APPLICATION

This application is a divisional of U.S. patent application Ser. No. 11/485,551 filed on Jul. 12, 2006. This application claims the benefit of Japanese Patent Application No. 2005-205470 filed Jul. 14, 2005. The disclosures of the above applications are incorporated herein by reference.

### BACKGROUND

1. Technical Field

The present invention relates to a manufacturing apparatus for an oriented film, a manufacturing method for an oriented film, a liquid crystal device and, an electronic device.

2. Related Art

A liquid crystal device has been used as a photo-modulation section in a projection display device such as a liquid crystal projector, etc.

Such a liquid crystal device includes a sealant arranged at the periphery between a pair of substrates and a liquid crystal layer sealed at its center.

Electrodes for applying a voltage to the liquid crystal layer are formed on the side of an inner surface of the pair of substrates, and an oriented film for controlling the orientation of liquid crystal molecules when applying a non-selective voltage is formed on the side of the inner surface of the electrodes.

By such a constitution, the liquid crystal device modulates the light of a light source based on the orientation change of the liquid crystal molecules when applying a non-selective voltage or selective voltage to form the light of an image.

An oriented film subjected to a rubbing treatment is generally used as the above-mentioned oriented film on the surface of a polymer film made of polyimides to which a side-chain alkyl group, etc, has been added.

The rubbing treatment section of a polymer is oriented in a pre-determined direction by rubbing the surface of a polymer film in a pre-determined direction with a roller having a soft cloth.

Liquid crystal molecules are arranged along an orienting high polymer due to an intermolecular interaction between the orienting high molecules and the liquid crystal molecules.

Therefore, liquid crystal molecules can be oriented in a pre-determined direction, when a non-selective voltage is applied.

A pre-tilt can be given to a liquid crystal molecule by a side-chain alkyl group.

However, when a liquid crystal device fitted with such an organic oriented film is adopted as the photo-modulation section of a projector, there is concern that the oriented film will gradually degrade due to strong light radiated from a light source or heat.

There is further concern that the orientation control function of liquid crystal molecules is reduced and the display quality of the liquid crystal projector will deteriorate after extended use, e.g., the liquid crystal molecules cannot be arrayed at a desired pre-tilt angle.

Accordingly, the use of an oriented film made of an inorganic material excellent in light resistance and heat resistance has been proposed.

As a manufacturing method for such an inorganic oriented film, for example, a silicon oxide (SiO₂) film formed by an oblique evaporation process is known.

When an inorganic oriented film is formed by the oblique evaporation process, it is necessary to control the incidence angle of an oriented film material to form the oriented film in a desired oriented state.

As a technique for controlling the incidence angle of an orientation material, Japanese Unexamined Patent Application, First Publication No. 2002-365639 is known.

According to this technique, a shielding plate having a slit is arranged between an oriented film material and a substrate, through which a desired oriented film is formed by selective evaporation at a pre-determined incidence angle.

Furthermore, according to this technique, the shielding plate and the substrate are adjacently arranged. By this means, evaporation is prevented on the substrate at an angle differing from the desired incidence angle by sublimating the evaporant between the shielding plate and the substrate.

Therefore, the oriented film having a desired evaporation angle without evaporation irregularities can be obtained.

However, since the oriented film material evaporated from an evaporator is sublimated to radially diffuse at the center of the evaporator, only a part of the oriented film material is evaporated on the substrate through the slit of the shielding plate, and another part of the oriented film material is adhered to the bottom of the shielding plate and an adhesion resistant plate arranged on an inner wall of a film formation chamber.

As described above, an amount of the adherence of the oriented film material on the inner walls of the chamber increases depending on the size of the substrate.

Thus, since the size of the film formation chamber is larger due to the size of the larger substrate, the distance between the evaporator and the substrate becomes greater, and the area on which the oriented film material is adhered is increased.

As a result, it is necessary to frequently perform maintenance, for example, removing the oriented film material adhered to the shielding plate or to the adhesion resistant plate by cleaning, and removing the oriented film material adhered to them by cleaning after changing shielding plates or adhesion resistant plates.

Therefore, productivity is lowered by increasing maintenance load.

### SUMMARY

An advantage of some aspects of the invention is to provide a manufacturing apparatus for an oriented film, a manufacturing method for an oriented film, a liquid crystal device and electronic device which reduce maintenance load and improve the productivity of manufacturing the oriented film.

A first aspect of the invention provides a manufacturing apparatus for manufacturing an oriented film of a liquid crystal device holding a liquid crystal between a pair of substrates facing each other, including: a film formation chamber; an evaporation section having an evaporation source, evaporating an oriented film material on the substrate by a physical vapor deposition, and forming the oriented film in the film formation chamber; a shielding plate arranged between the evaporation section and the substrate, having an elongated opening for selectively evaporating the oriented film material, and covering an area of the substrate on which the oriented film is not formed; and a first regulating member arranged between the evaporation source and the shielding plate and at a position closer to the evaporation source than from the shielding plate, regulating a sublimating direction in which the oriented film material is sublimated.

According to this manufacturing apparatus, the first regulating member regulating the sublimating direction of the evaporant evaporated from the evaporation source is arranged at a portion closer to the evaporation source than from the shielding plate so that it is possible to reduce the amount of the oriented film material which adheres to the bottom of the shielding plate or to the adhesion resistant plate installed to the inner wall of the film formation chamber by the first regulating member, when the evaporation is performed.

Therefore, it is possible to reduce the maintenance load to remove the oriented film material adhered to the shielding plate or to the adhesion resistant plate, and thus productivity can be improved.

It is preferable that, in the manufacturing apparatus for manufacturing the oriented film of the first aspect of the invention, the first regulating member have a slit which is openable and closable for regulating the sublimating direction toward the opening of the shielding plate.

In prior art, there is concern that when the oriented film material is sublimated by the evaporation section, the sublimation rate of the evaporation source is not stabilized in the initial stage of sublimation of the oriented film material. Thus, irregularities in the oriented film formed by the evaporation occur in the initial stage of the evaporation.

However, according to the manufacturing apparatus for manufacturing the oriented film, it is possible to stop the evaporation until the sublimation rate of the evaporation source stabilizes by closing the slit regulating of the first regulating member.

Thus, it is possible to prevent the adherence of the oriented film material to inside the film formation chamber while covering the evaporation source.

It is preferable that the manufacturing apparatus for manufacturing the oriented film of the first aspect of the invention, further include: an adhesion resistant member arranged at the first regulating member, covering a side of the evaporation source.

According to this structure, it is possible to prevent the adherence of the oriented film material which is sublimated from the evaporation source and flows to a side of the evaporation source to, for example, an adhesion resistant plate installed on the inner wall of the film formation chamber.

In addition, it is possible to adhere the oriented film material to the adhesion resistant member installed on the first regulating member.

Therefore, it is possible to reduce the maintenance load to remove the oriented film material adhered to the adhesion resistant plate. Thus, productivity can be improved.

It is preferable that the manufacturing apparatus for manufacturing the oriented film of the first aspect of the invention, further include: a second regulating member arranged between the shielding plate and the first regulating member, and further regulating a sublimating direction in which the oriented film material be sublimated in the sublimating direction regulated by the first regulating member.

According to this structure, the sublimating direction of the evaporant evaporated from the evaporation source is regulated with high precision by these regulating members (first regulating member and second regulating member). It is possible to deliver the evaporant to the opening of the shielding plate without spreading the evaporant on the side of the shielding plate.

Therefore, the adherence of the oriented film material to the shielding plate and the adhesion resistant plate can be reduced, and it is possible to reduce the maintenance load as well.

It is preferable that, in the manufacturing apparatus for manufacturing the oriented film of the first aspect of the invention, a plurality of the second regulating members be arranged between the shielding plate and the first regulating member, and positions of the second regulating members through which the evaporated oriented film material is passed be substantially aligned in one direction.

According to this structure, it is possible to regulate the sublimating direction of the evaporant evaporated from the evaporation source with higher precision by these regulating members.

It is preferable that, in the manufacturing apparatus for manufacturing the oriented film of the first aspect of the invention, the shielding plate have a plurality of the elongated openings.

In the case in which the oriented film material is evaporated on the substrate through the opening of the shielding plate, one part of the oriented film material is adhered to an inner-edge of the opening of the shielding plate via the opening.

Therefore, the slit width of the elongated opening is narrowed. Evaporation conditions such as the incidence angle regulated by the opening are changed compared to an initial evaporation condition.

Accordingly, the shielding plate has a plurality of the elongated openings so that it is possible to evaporate the oriented film material on the substrate by substituting an opening of which the oriented film material is adhered on the inner-edge, to an opening of which the oriented film material is not adhered on the inner-edge.

By this means, it is possible to perform a stabilized evaporation in the initial evaporation condition.

Specifically, the sublimating direction of the evaporant sublimated from the evaporation source is substantially regulated so that the oriented film material sublimated from the evaporation source selectively flows into one opening selected from among the plurality of openings of the shielding plate.

In the case in which the oriented film material is adhered to the inner-edges of one of the openings, the other opening is adjusted to the sublimating direction by shifting the shielding plate relative to the sublimating direction. Therefore, it is possible to perform stabilized evaporation in the initial evaporation condition.

It is preferable that, in the manufacturing apparatus for manufacturing the oriented film of the first aspect of the invention, a width of the opening of the shielding plate be variable.

According to this structure, when it is necessary to change the incidence angle or the like of the oriented film material regulated by the opening due to changing the evaporation condition (sublimation condition) or due to a pretreatment condition of the substrate, it is possible to easily change an undesirably condition to a desirably condition by changing the width of the variable opening of the shielding plate.

A second aspect of the invention provides a manufacturing method for an oriented film including: sublimating an oriented film material from an evaporation source; regulating a sublimating direction in which the oriented film material is sublimated, by a regulating member arranged at a portion closer to the evaporation source than from the shielding plate; passing the oriented film material through an elongated opening of a shielding plate; depositing the oriented film material on a substrate by a physical vapor deposition.

According to this manufacturing method, when the oriented film material is evaporated through the opening of the shielding plate, since a sublimating direction of the evaporant is regulated by the regulating member arranged at a portion closer to the evaporation source than from the shielding plate, it is possible to reduce the amount of the oriented film material that adheres to the bottom of the shielding plate or to the adhesion resistant plate installed on the inner wall of the film formation chamber by the regulating member.

Therefore, it is possible to reduce maintenance load in which the oriented film material adhered to the shielding plate or to the adhesion resistant plate is removed. Thus, productivity can be improved.

A third aspect of the invention provides a liquid crystal device including the oriented film manufactured by the above-described manufacturing method.

With regard to the liquid crystal device, since productivity of manufacturing the oriented film can be improved, productivity of manufacturing the liquid crystal device can be also improved.

A fourth aspect of the invention provides an electronic device including the above-described liquid crystal device.

Thus, since the electronic device includes the liquid crystal device with improved productivity, the productivity of the electronic device is also improved.

### BRIEF DESCRIPTION OF THE DRAWINGS

FIG. 1 is a cross-sectional view of an embodiment of the manufacturing apparatus of this invention.

FIG. 2 is a perspective view for describing a schematic block diagram of the regulating member.

FIG. 3A is a perspective view for describing a schematic block diagram of the shielding plate on which a plurality of openings is formed, and FIG. 3B is a plan view for describing a schematic block diagram of the shielding plate on which a plurality of openings is formed.

FIG. 4 is a cross-sectional view for describing the state of vicinity of the opening of the shielding plate.

FIG. 5 is a plan view of a TFT array substrate of a liquid crystal device.

FIG. 6 is an equivalent circuit diagram of the liquid crystal device.

FIG. 7 is a plan view showing a structure of the liquid crystal device for describing the liquid crystal device.

FIG. 8 is a cross-sectional view showing a structure of the liquid crystal device for describing the liquid crystal device.

FIG. 9 is a schematic block diagram showing a projector.

### DESCRIPTION OF EXEMPLARY EMBODIMENTS

The invention is described in detail hereinafter with reference to the drawings.

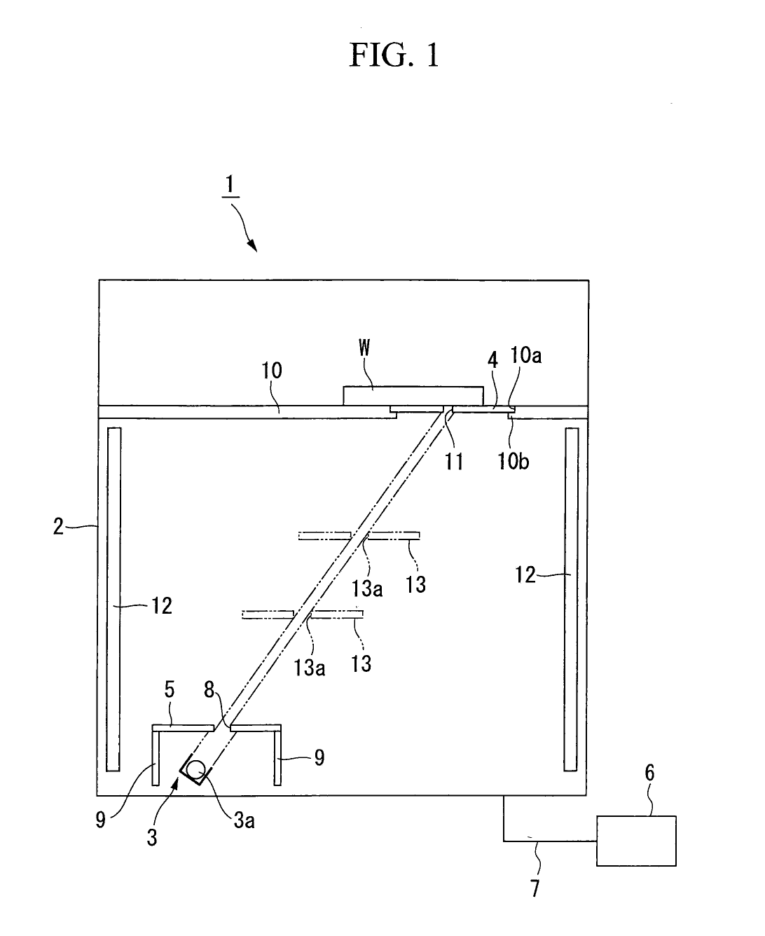

FIG. 1 is a cross-sectional view of an embodiment of the manufacturing apparatus of this invention and for describing a schematic block diagram of the manufacturing apparatus.

In FIG. 1, reference numeral 1 represents a manufacturing apparatus for manufacturing an oriented film (hereinafter referred to as manufacturing apparatus).

The manufacturing apparatus 1 forms an oriented film made of an inorganic material on the surface of a substrate W constituting a constituent member of the liquid crystal device.

The manufacturing apparatus 1 includes a film formation chamber 2 constituted as a vacuum chamber, an evaporation section 3 for sublimating an inorganic material of which the oriented film material is made, a shielding plate 4 arranged between the evaporation section 3 and the substrate W, and a regulating member (first regulating member) 5 for regulating a sublimating direction of the evaporant evaporated from the evaporation source 3a.

The film formation chamber 2 communicates with a pre-processing chamber (not shown) in which the substrate W is subjected to a pretreatment for the forming of the oriented film (e.g., heating treatment for substrate W) and with a post-processing chamber (not shown) in which the substrate W is subjected to an after-treatment for the forming of the oriented film (e.g., cooling treatment for substrate W).

Gate valves tightly isolating the film formation chamber 2 from the pre-processing chamber and from the post-processing chamber are provided.

In such a constitution, it is possible to transfer the substrates W from the pre-processing chamber to the film formation chamber 2, and is possible to transfer the substrates W from the film formation chamber 2 to the post-processing chamber, without greatly lowering the vacuum in the film formation chamber 2.

A transporting section (not shown) is connected to the film formation chamber 2. The transporting section receives the substrate W from the pre-processing chamber, continuously or intermittently transports the substrates W in the film formation chamber 2, and sends the substrates W out from the film formation chamber 2 toward the post-processing chamber.

A vacuum pump 6 for controlling the inner pressure to obtain a desired vacuum state is connected to the film formation chamber 2 via a pipe 7.

The evaporation section 3 is arranged at the bottom of the film formation chamber 2 and at the side of the inner wall of the film formation chamber 2.

The evaporation section 3 evaporates inorganic material, which becomes the oriented film material on the substrates W by a physical vapor deposition process, i.e., an evaporation process or a sputtering process such as an ion beam sputtering process, etc. to form the oriented film.

In the embodiment, the evaporation section 3 includes an evaporation source 3a made of the inorganic material and an electron beam gun unit (not shown) which radiates an electron beam on the evaporation source 3a to heat and sublimate the inorganic material.

As heating types of the evaporation source 3a in place of the electron beam gun unit, a resistance heating type heater may be used.

Here, silicon oxide (SiOₓ) such as silicon dioxide (SiO₂) used as the inorganic material functions as the oriented film material in this embodiment.

In the evaporation section 3, the opening of a crucible that holds the evaporation source 3a is aligned with an opening of the shielding plate 4 as described later, thereby the evaporation section 3 selectively sublimates an evaporant of the inorganic material mainly in a direction shown by a double chain line in FIG. 1.

The sublimating direction of evaporant of the oriented film material is limited by the opening of the crucible. However, when the evaporant sublimates from the opening of the crucible partway, then the evaporant is sublimated to radially diffuse at the center of the evaporator 3a.

Accordingly, in this invention, the regulating member 5 is arranged between the evaporation source 3a and the shielding plate 4 and at a portion closer to the evaporation source 3a than from the shielding plate 4 in order to regulate the flow (diffuseness) of the evaporant of the oriented film material evaporated from the evaporator 3a, namely the sublimating direction of the evaporator 3a, to an opening of the shielding plate 4 and in the vicinity of the opening as will be described later.

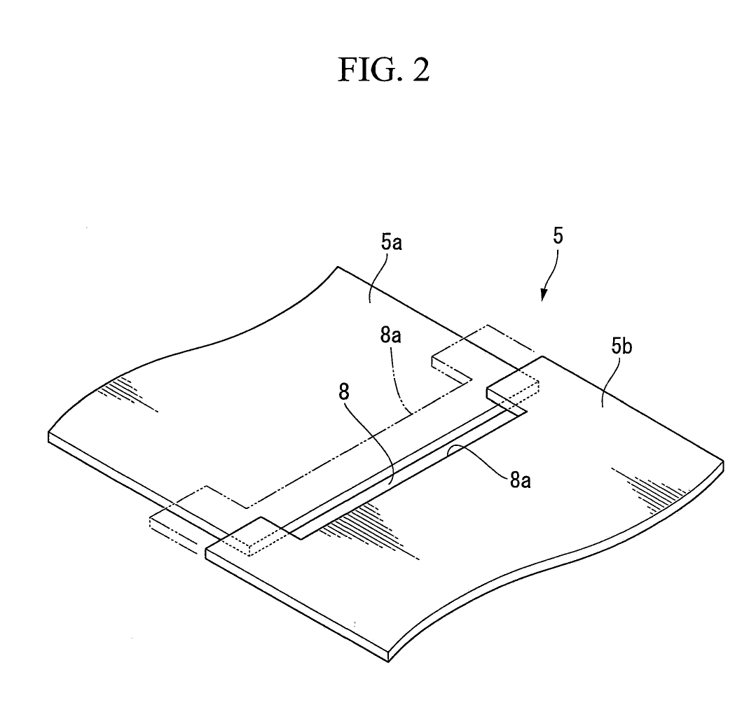

As shown in FIG. 2, the regulating member 5 includes a pair of regulating plates 5a and 5b, and has a slit 8 between the regulating plates 5a and 5b.

Accordingly, the regulating member 5 includes the regulating plate 5a shaped rectangularly and the regulating plate 5b shaped substantially rectangularly. The regulating plate 5b has a notch 8a formed on a side limbus of the regulating plate 5b that faces the regulating plate 5a. The slit 8 is formed between the regulating plate 5a and the notch 8a.

The slit 8 is arranged at a position on a crossline between the evaporator 3a and the opening of the shielding plate 4, thereby the sublimating direction of the evaporator 3a is regulated to the opening of the shielding plate 4 and in the vicinity of the opening.

Furthermore, the regulating member 5 includes a forward/backward mechanism (not shown), thereby the regulating plate 5b is movable forward and backward relative to the regulating plate 5a.

In such a structure, the notch 8a is covered by the regulating plate 5a as shown by a double chain line in FIG. 2, thereby the regulating member 5 can close the slit 8. Therefore, the regulating member 5 has the slit 8 which is openable and closable.

Therefore, the forming of film on the substrates W can be stopped until the sublimation rate of the evaporation source 3a stabilizes by closing the slit 8 and by covering the evaporation source 3a with the regulating member 5, especially in the initial stage of sublimation of an orientation material, as will be described later.

Furthermore, an adhesion resistant member 9 covering a side of the evaporation source 3a is arranged at the outer periphery of the regulating member 5.

The adhesion resistant member 9 is made of a plate arranged to suspend from the outer periphery of the regulating member 5.

The adhesion resistant member 9 covers an outer side of the evaporation source 3a, thereby the sublimated oriented film material flowing from the evaporation source 3a to the side of the evaporation source 3a does not flow to the inner wall of the film formation chamber 2, is obstructed by the adhesion resistant member 9, and is adhered to the adhesion resistant member 9.

The shielding plate 4 is attachably/detachably held and fixed at a transporting plate 10 installed in the film formation chamber 2 and is made of a metal, ceramic, resin, or the like.

The transporting plate 10 holds the substrate W on or above the upper face of the transporting plate 10, and allows the substrate W to be movable by the transporting section (not shown).

An opening 10a holding the shielding plate 4 is formed in the transporting plate 10. The opening 10a is positioned at a side of an inner wall opposite side at which the evaporation section 3 is arranged.

A holding portion 10b extending from the inner wall of the opening 10a to the inside of the opening 10a is formed in the opening 10a of the transporting plate 10.

By this means, the shielding plate 4 is held and fixed on the transporting plate 10, while the shielding plate 4 is fit into the opening 10a and is mounted on the holding portion 10b.

Furthermore, an elongated opening 11 having a predetermined width is formed in the shielding plate 4.

An extending direction of the opening 11 is orthogonally positioned to the direction for transporting the substrate W by properly arranging the shielding plate 4 relative to the substrate W. The oriented film material sublimated from the evaporation section 3 passes through the opening 11, and is selectively evaporated and deposited on the substrate W.

Furthermore, the opening 11 is arranged so as to set an angle between the surface of the substrate W exposed by the opening 11 and a sublimating direction from the evaporation source 3a to the opening 11 in a predetermined angle range.

Hence, the sublimate (evaporant) of the oriented film material is obliquely evaporated and deposited at a predetermined angle on the film formation surface of the substrate W.

The opening 11 is substantially arranged on an elongation connecting the evaporator 3a and the slit 8 of the regulating member 5.

In such structure, the evaporant sublimated from the evaporator 3a is regulated by the slit 8 of the regulating member 5, thereby the evaporant is not sublimated to radially diffuse and flows into only the opening 11 of the shielding plate 4 and in the vicinity of the opening 11 as intended.

On the other hand, the shielding plate 4 covers a oriented film non-formation area, i.e., an area other than the film formation area delimited by the opening 11, by covering the bottom surface of the substrate W, thereby prevents the oriented film material from evaporating onto the oriented film non-formation area.

Since the substrate W is moved relative to the opening 11, the oriented film material can be obliquely evaporated over an entirely of the film formation area by partially exposing the film formation area (oriented film formation area) of the substrate W to the opening 11 in a step-by-step manner.

In the film formation chamber 2, adhesion resistant plates 12 are removably arranged on the inner wall of the film formation chamber 2.

Next, the manufacturing method for the oriented film by the manufacturing apparatus 1 and maintenance for the manufacturing apparatus 1 are described.

First, inside the film formation chamber 2 is regulated to a desired vacuum state by operating the vacuum pump 6 and inside the film formation chamber 2 is regulated to a desired temperature by a heater (not shown).

In addition, the slit 8 is separately closed by the regulating member 5 by closing the regulating plate 5a and 5b of the regulating member 5, thereby the evaporation source 3a is covered by the regulating member 5.

In this state, the evaporation source 3a is operated in order to sublimate an oriented film material.

Subsequently, if the sublimation rate of the evaporation source 3a is stabilized, the slit 8 is opened by moving the regulating plate 5a relative to the regulating plate 5b, thereby exposing the evaporation source 3a.

Because the evaporation source 3a is exposed through the slit 8, it is possible to regulate the flowing direction (sublimating direction) of the oriented film material evaporated from the evaporation source 3a by this slit 8.

Thus, it is possible to regulate so that the evaporated oriented film material passed through the slit 8 flows into only the opening 11 of the shielding plate 4 and in the vicinity of the opening 11 as intended, in a direction shown by a double chain line in FIG. 1.

In the oriented film material sublimated from the evaporation source 3a, the flow of the oriented film material is interrupted by the adhesion resistant member 9 and the regulating member 5, thereby the oriented film material which does not pass through the slit 8 of the regulating member 5 is adhered to the adhesion resistant member 9 and the regulating member 5.

Thus, the regulating member 5 and the adhesion resistant member 9 prevent the flowing of the evaporant and the adhering of the evaporant to the shielding plate 4 or adhesion resistant plates 12 arranged on the inner wall of the film formation chamber 2.

Subsequently, the substrate W which has been a pretreatment such as heating or the like in the pre-processing chamber is transferred into the film formation chamber 2.

Then, the substrate W is continuously or intermittently transported.

While sublimating the oriented film material such as above, the substrate W is moved on the transporting plate 10, the substrate W is reached on the shielding plate 4, and film formation surface of the substrate W is exposed via the opening 11.

In this case, since the opening 11 is arranged so as to set an angle between the surface of the substrate W exposed by the opening 11 and a sublimating direction from the evaporation source 3a to the opening 11 in a predetermined angle range, the oriented film material sublimated from the evaporation source 3a is obliquely evaporated at a predetermined angle to the film formation surface of the substrate W.

Then, the oriented film material can be obliquely evaporated and deposited over the surface of the film formation area (oriented film formation area) of the substrate W and a desired oriented film can be formed by such oblique evaporating while continuously or intermittently moving the substrate W relative to the opening 11.

According to such a constituted manufacturing apparatus 1, the regulating member 5 regulating a sublimating direction of the evaporant evaporated from the evaporation source 3a is arranged between the evaporation source 3a and the shielding plate 4 and at a portion closer to the evaporation source 3a than from the shielding plate 4, thereby it is possible to remarkably reduce the amount of oriented film material which adheres to the bottom of the shielding plate 4 or to the adhesion resistant plate 12 installed on the inner wall of the film formation chamber 2 by the regulating member 5, when the evaporation is performed.

Therefore, it is possible to reduce the maintenance load in which the oriented film material adhered to the shielding plate 4 or to the adhesion resistant plate 12 is removed. Thus productivity can be improved.

In the prior art, there is concern that when the oriented film material is sublimated by the evaporation section 3, the sublimation rate of the evaporation source is not stabilized in the initial stage of sublimation of the oriented film material. Thus, irregularities in the oriented film formed by the evaporation occur in the initial stage of the evaporation.

In contrast, in the manufacturing apparatus 1, it is possible to stop the evaporation until the sublimation rate of the evaporation source 3a stabilizes by closing the openable and closable slit 8 regulating the sublimating direction of the regulating member 5.

Then, it is possible to prevent the adherence of the oriented film material to inside the film formation chamber 2 by covering the evaporation source 3a with the regulating member 5, when stopping the forming of the oriented film.

Furthermore, the adhesion resistant member 9 covering a side of the evaporation source 3a is arranged at the regulating member 5, it is possible to prevent the adherence of the oriented film material which sublimates from the evaporation source 3a and flows to a side of the evaporation source 3a to, for example, an adhesion resistant plate 12 installed on the inner wall of the film formation chamber 2.

Thus, it is possible to adhere the oriented film material to the adhesion resistant member 9 installed on the regulating member 5.

Therefore, it is possible to reduce the maintenance load in which the oriented film material adhered to the adhesion resistant plate 12 is removed. Thus, productivity can be improved.

This invention is not limited to the above-mentioned embodiment, and embodiments added with various modifications to the above-mentioned embodiment are also included within parameters which do not deviate from the purpose or scope of the invention.

For example, a second regulating member 13 further regulating the sublimating direction regulated by the regulating member 5 may be arranged between the regulating member 5 and the shielding plate 4 as shown by a double chain line in FIG. 1. In this case, a plurality of the second regulating members 13 may be arranged.

Here, a slit 13a is formed on each of these second regulating members 13, similar to the above described regulating member 5. The slit 13a further regulates the sublimating direction of the oriented film material sublimated from the evaporation source 3a.

In this manner, the sublimating direction of the evaporation source 3a is regulated by also the second regulating members 13 in addition to the regulating member 5, thereby the sublimating direction is regulated with higher precision. Therefore, the oriented film material is not sublimated to radially diffuse to the shielding plate 4, thereby it is possible to reliably evaporate and deposit the oriented film material on the substrate W through the opening 11 of the shielding plate 4.

Thus, it is possible to further reduce the amount of oriented film material which adheres to the shielding plate 4 or to the adhesion resistant plate 12, and reduce the maintenance load of operation.

Furthermore, in the case in which a plurality of the second regulating members 13 is arranged in especially, it is preferable that positions (slits 13a) of the second regulating members 13 through which the evaporated oriented film material is passed be substantially aligned in one direction.

In this manner, it is possible to regulate the sublimating direction of the evaporant evaporated from the evaporation source 3a with higher precision by these regulating members 5 and 13.

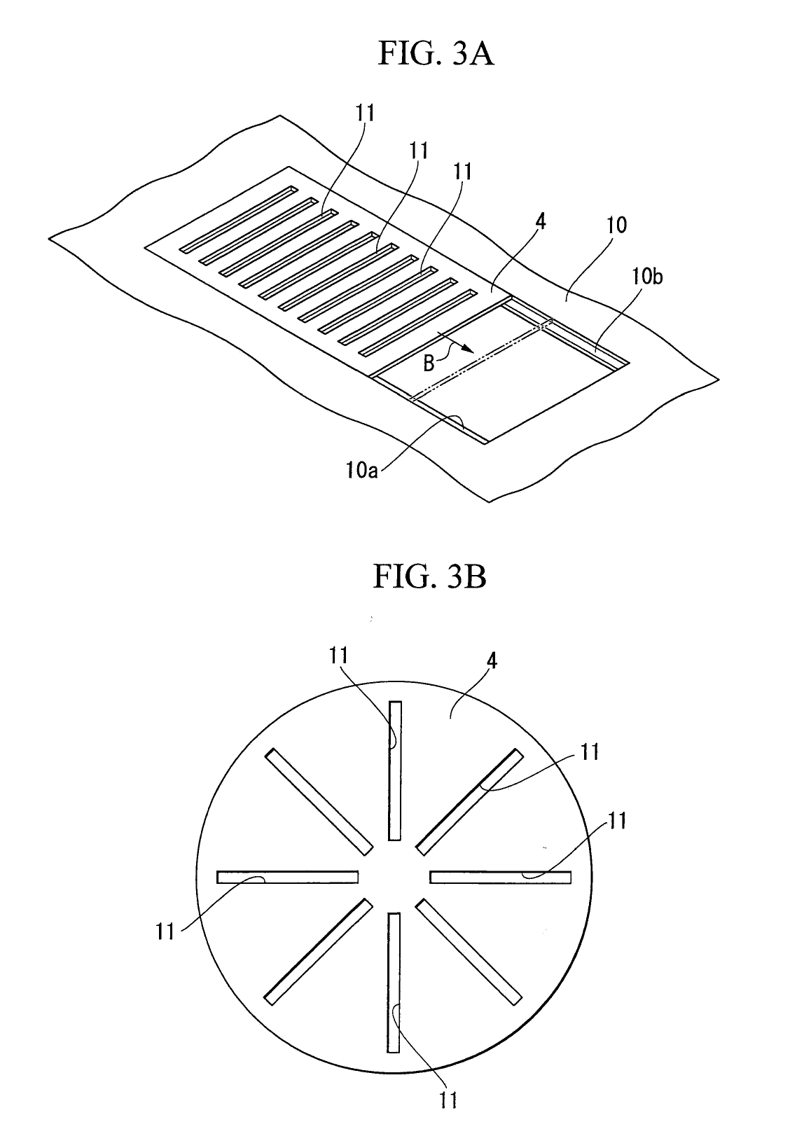

Furthermore, one elongated opening 11 is formed on the shielding plate 4 as described above, a plurality of the elongated openings 11 is formed on the shielding plate 4 to arrange in parallel with constant pitch in an orthogonal direction relative to a length direction of the openings 11 may be used as a perspective view shown in FIG. 3A.

In this case, the shielding plate 4 is held by the transporting plate 10 and movable relative to the transporting plate 10.

For example, as shown in FIG. 3, the length of the opening 10a of the transporting plate 10 is well-lengthened relative to that of the shielding plate 4. The shielding plate 4 is movable by a moving mechanism (not shown), in the opening 10a, in an arrow direction B shown in FIG. 3A, in increments of a predetermined distance (distance of a pitch between the openings 11).

In this manner described above, in the case in which the oriented film material is adhered to the inner-edges of one opening 11 partway, the used opening 11 which has been used for the evaporation is shifted from the position of the sublimating direction, and an unused opening is adjusted to the sublimating direction by moving the shielding plate 4. Thereby it is possible to form the oriented film again by using an unused opening 11.

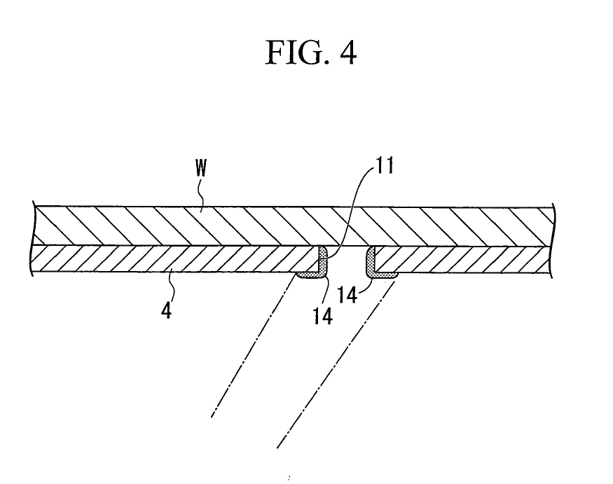

Specifically, with regard to the forming of the oriented film material by the evaporation described above, it is impossible to evaporate and deposit the oriented film material sublimated from the evaporation section 3 on the substrate W through only the opening 11, the oriented film material is adhered in the vicinity of the opening 11 at the bottom of the shielding plate 4, further to the inner-edges of the opening 11 in general as shown in FIG. 4.

The amount of adherence of the oriented film material 14 increases depending on how long the evaporation is performed. Therefore, there is concern that the film performance is degraded because of this.

In order to solve such a concern, it is necessary to frequently perform maintenance on inside the film formation chamber 2 such as changing the shielding plate 4. However, productivity is lowered in this case.

This is because no matter how the evaporation is performed in a vacuum, when maintenance for inside the film formation chamber 2 is performed, it is necessary to adjust the pressure of the inside apparatus from a vacuum to an atmospheric pressure.

Therefore, it is necessary to adjust the desired pressure by suctioning the air from inside the film formation chamber 2 for evaporating again after maintenance.

However, suctioning the air from inside the film formation chamber 2 takes time. For example, in the case of evaporating a large substrate from which a plurality of substrates is taken, the evaporating apparatus must be large, and there is a substantial need for ten hours to one day to suction the air from inside the film formation chamber 2.

Accordingly, in this invention, the openings 11 are formed on the shielding plate 4 as shown in FIG. 3A, the used opening 11 is shifted by moving the shielding plate 4, and the oriented film material is evaporated and deposited by using the unused opening 11 described above, after the forming of the oriented film has been performed during a predetermined time.

In this manner, it is possible to form the oriented film in an initial evaporating condition in stability, further to minimally suppress the reduction of productivity due to that the suctioning of the air from inside the film formation chamber 2 in order to exchange the shielding plate 4.

In addition, in the case in which the elongated openings 11 are formed on a disciform shielding plate 4, the elongated openings 11 may be radially formed relative to the center of the shielding plate 4 with constant circular pitch as a plan view shown in FIG. 3B. In this case, the shielding plate 4 is rotatably held relative to the transporting plate 10.

Thus, the shielding plate 4 can be rotated in the opening 10a in increments of a predetermined angle by a rotating mechanism (not shown) can rotate, thereby the unused opening 11 is shifted to the position of the used opening 11, and this operation is repeated.

In the composition described above, similar to the case of the shielding plate 4 shown in FIG. 3A, in the case in which the oriented film material is adhered to the inner-edges of one opening 11 partway, the used opening 11 is shifted by rotating the shielding plate 4, thereby it is possible to form the oriented film again by using an unused opening 11.

Therefore, in this manner, it is possible to form the oriented film in an initial evaporating condition in stability, further to minimally suppress the reduction of productivity due to that the suctioning of the air from inside the film formation chamber 2 in order to exchange the shielding plate 4.

Here, it is possible to desirably obtain the above described effects by forming the openings 11 on the shielding plate 4 as shown in FIGS. 3A and 3B, because the sublimating direction of the evaporation source 3a is regulated by the regulating member 5 partway in this invention.

Thus, the sublimating direction of the evaporation source 3a is regulated by the regulating member 5 partway, thereby the oriented film material evaporated from the evaporation source 3a substantially and selectively flows into an opening 11 selected from among the openings 11 of the shielding plate. The selected opening 11 is positioned at the sublimating direction of the evaporation source 3a.

Thus, in the case in which the oriented film material is adhered to the inner-edges of one of the openings 11, the other opening is adjusted to the sublimating direction of the evaporation source 3a by moving the shielding plate 4. Therefore, it is possible to form the oriented film in an initial evaporating condition in stably.

Specifically, if a part of the oriented film material adheres to the inner-edges of the opening 11 when the oriented film material passes the inside of the opening 11, the width of the elongated opening 11 becomes narrower than before. Thereby, an evaporating condition including the incidence angle regulated by the openings 11 is changed compared with an initial evaporating condition.

Accordingly, it is possible to form the oriented film in an initial evaporating condition of stability because of changing the used opening 11 to the unused opening 11 described above.

In the above described embodiment, a width of the elongated opening 11 is a constant width. With regard to the shielding plate 4, the width of the opening 11 may be variable by adopting the same composition as the regulating member 5 as shown in FIG. 2.

Such a composition, when it is necessary to change the incidence angle or the like of the oriented film material regulated by the opening 11 due to changing the evaporation condition (sublimation condition) or due to a pretreatment condition of the substrate, it is possible to easily change an undesirable condition to a desirable condition by changing the width of the variable opening 11 of the shielding plate 4.

Next, a liquid crystal device of this invention provided with the oriented film formed by the manufacturing method based on such manufacturing apparatus 1 is described.

The scale of members is suitably changed to make the members recognizable sizes in the drawings used in the following description.

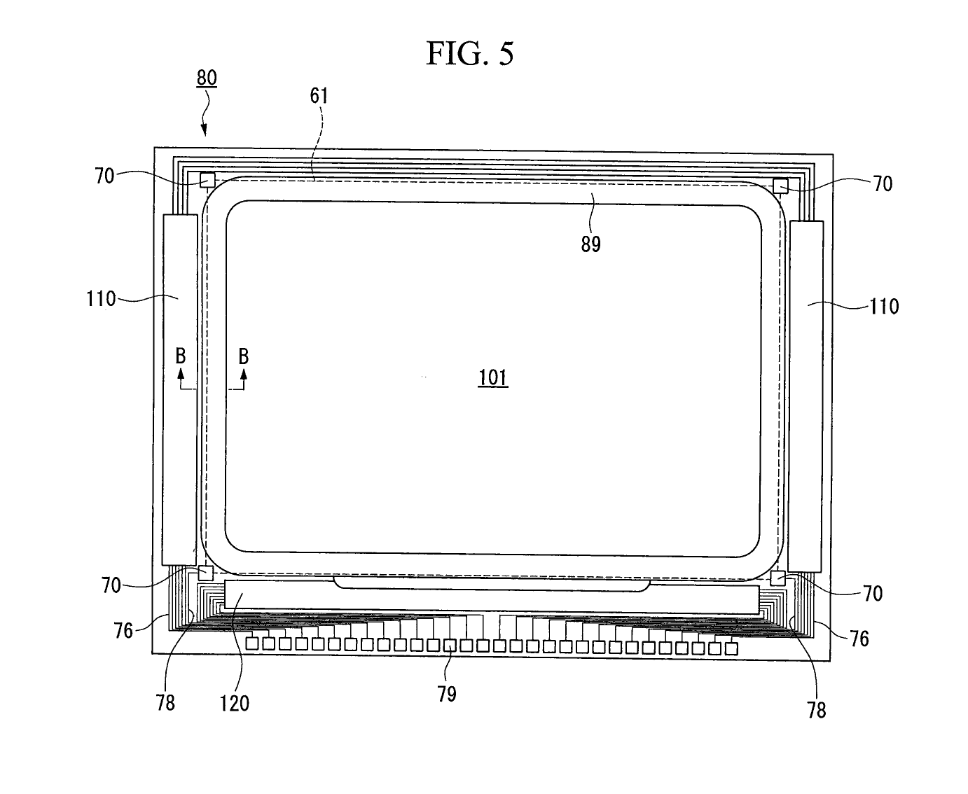

FIG. 5 is a plan view of a TFT array substrate showing a schematic constitution of an embodiment of the liquid crystal device of this invention.

Reference numeral 80 is the TFT array substrate in FIG. 5.

An image forming area 101 is formed at the center of the TFT array substrate 80.

A sealant 89 is arranged at the periphery of the image forming area 101, and a liquid crystal layer (not shown) is sealed in the image forming area 101.

The liquid crystal layer is formed by directly applying a liquid crystal onto the TFT array substrate 80, becoming a so-called seal-less structure in which an injection port of liquid crystal is not provided for the sealant 89.

Scanning line driving elements 110 for supplying a scanning signal to scanning lines described later and a data line driving element 120 for supplying an image signal to data lines described later are mounted to the outer side of the sealant 89.

Wirings 76 are drawn around from the driving elements 110 and 120 to connection terminals 79 of the end of the TFT array substrate 80.

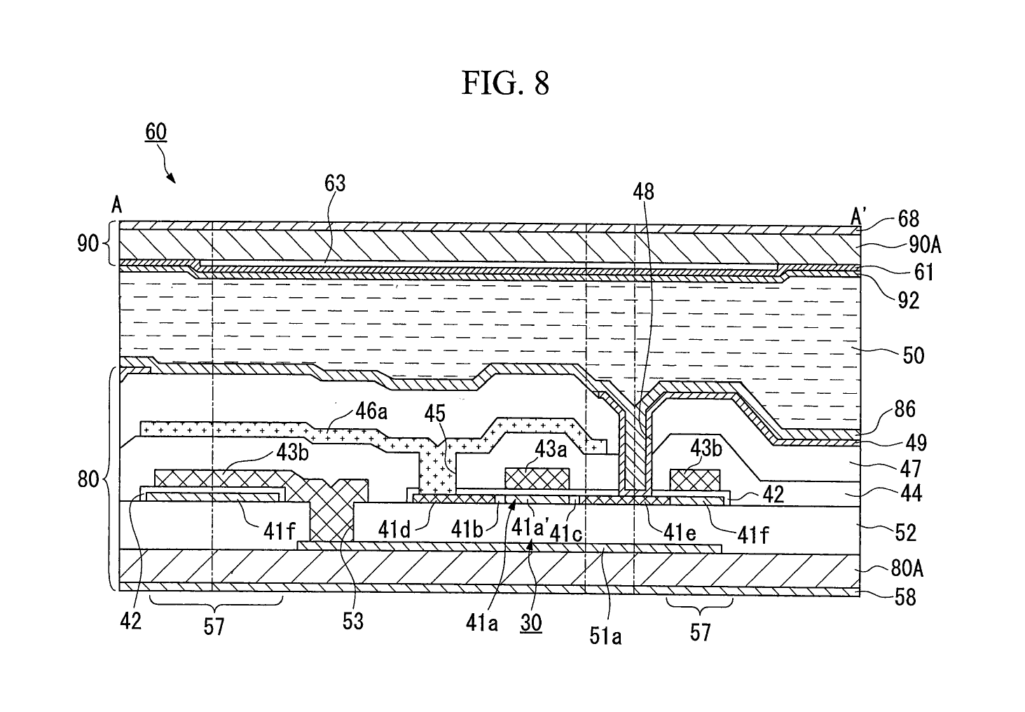

On the other hand, a common electrode 61 (show in FIG. 8) is formed on a facing substrate 90.

This common electrode 61 is formed over nearly the entire image forming area 101, and conducting parts 70 between substrates 80 and 90 are formed at four corners thereof.

Wirings 78 are drawn from conduction parts 70 between substrates 80 and 90 to the connection terminals 79.

Then, the liquid crystal device is driven by supplying various signals input from the outside to the image forming area 101 via the connection terminals 79.

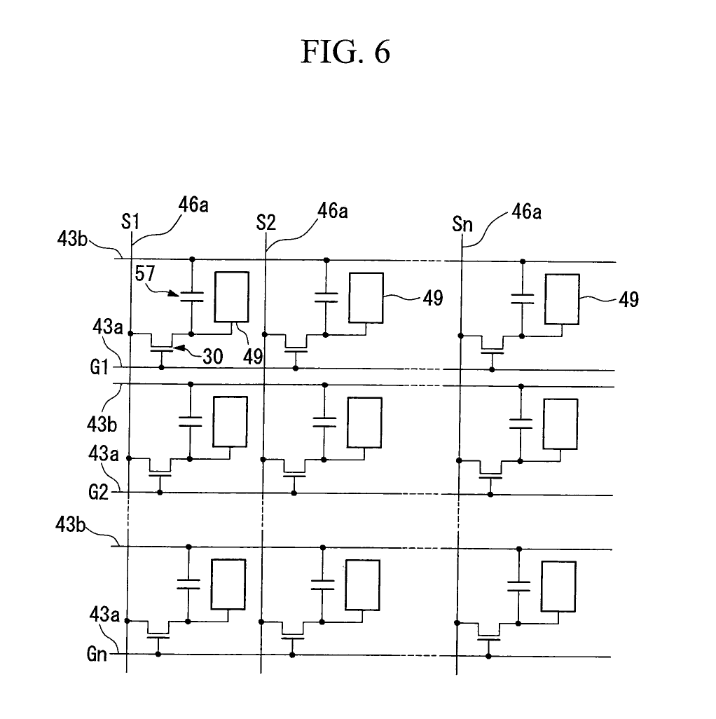

FIG. 6 is an equivalent circuit of the liquid crystal device.

Each of pixel electrodes 49 is formed in each of plurality of image elements arranged in an arrayed arrangement (matrix arrangement) which construct the image forming area 101 of a transmission-type liquid crystal device.

Moreover, TFT elements 30 including switch elements for performing control of energization of the pixel electrodes 49 are formed on the side portion of the pixel electrodes 49.

Data lines 46a are connected to sources of these TFT elements 30.

Image signals S1, S2, - - - , Sn are supplied from the above-mentioned data line driving element 120 to the each of data lines 46a.

Scanning lines 43a are connected to gates of the TFT elements 30.

Scanning signals G1, G2, - - - , Gm are supplied from the above-mentioned scanning line driving elements 110 to the each of scanning lines 43a in pulses at a predetermined timing.

On the other hand, the pixel electrodes 49 are connected to drains the of TFT elements 30.

If the TFT elements 30 including switch elements are turned ON only in a given period, the image signals S1, S2, - - - , Sn supplied from the data lines 46a are written in the liquid crystal of image elements at a predetermined timing via the pixel electrodes 49 by the scanning signals G1, G2, - - - , Gm supplied from the scanning lines 43a.

The image signals S1, S2, - - - , Sn at a predetermined level written in the liquid crystal are held for a given period by liquid crystal capacities formed between the pixel electrodes 49 and the common electrode 61 described later.

Accumulative capacities 57 are formed between the pixel electrodes 49 and capacity lines 43b and are arranged in parallel to the liquid crystal capacities to prevent the held image signals S1, S2, - - - , Sn from leakage.

Thus, if a voltage signal is applied on the liquid crystal, the oriented state of liquid crystal molecules changes with the applied voltage level.

Thereby, light of the light source entering the liquid crystal is modulated to form light of an image.

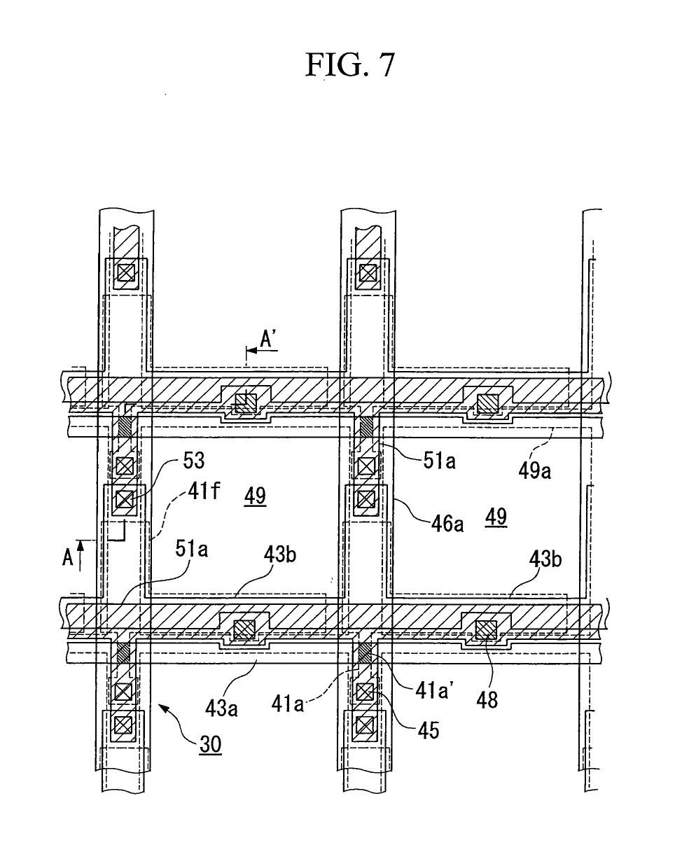

FIG. 7 is a plan view of the planar structure of the liquid crystal device.

In the liquid crystal device of this embodiment, rectangular pixel electrodes 49 (their contours are shown by broken lines 49a) made of a transparent conductive material, such as Indium Tin Oxide (referred to as ITO hereinafter), are arrayed in an arrayed arrangement (matrix arrangement) on a TFT array substrate.

The data lines 46a, scanning lines 43a and capacity lines 43b are provided along vertical and horizontal boundaries of the pixel electrodes 49.

In this embodiment, the rectangular area formed with the pixel electrodes 49 includes image elements and becomes a structure capable of performing a display for each dot arranged in an arrayed arrangement.

The TFT elements 30 are formed with a semiconductor layer 41 made of a polysilicon film, etc., and position at the center of the semiconductor layer 41.

The data lines 46a are connected to a drain region (described later) of the semiconductor layer 41 via connector holes 45.

The pixel electrodes 49 are connected to a source region (to be described later) of the semiconductor layer 41 via connector holes 48.

On the other hand, a channel region 41′ is formed in a section faced to the scanning line 43a in the semiconductor layer 41.

FIG. 8 is a cross-sectional view of a sectional structure of the liquid crystal device taken along the line A-A′ of FIG. 7.

As shown in FIG. 8, a liquid crystal device 60 of this embodiment is provided with a TFT array substrate 80, a facing substrate 90 arranged faced to the TFT array substrate 80, and a liquid crystal layer 50 held between the substrates 80 and 90 as the main body.

The TFT array substrate 80 is provided with the substrate body 80A made of a translucent material such as glass or quartz, the TFT element 30, the pixel electrode 49 formed at an inner side of the substrate body 80A, the inorganic oriented film 86, etc. as the main body.

On the other hand, the facing substrate 90 is provided with a substrate body 90A made of a translucent material such as glass or quartz, the common electrode 61 formed at an inner side of the substrate body 90A, the inorganic oriented film 92, etc. as main body.

A first shading film 51 and a first interlayer insulating film 52 described later are formed at the surface of the TFT array substrate 80.

Then, the semiconductor layer 41 is formed on the surface of the first interlayer insulating film 52, and the TFT element 30 is formed with this semiconductor layer 41 as the center.

The channel region 41′ is formed in a portion faced to the scanning line 43a at the semiconductor layer 41, and a source region and a drain region are formed at both sides of the semiconductor layer 41.

An LDD (Lightly-Doped Drain) structure is adopted in the TFT element 30, therefore a high-concentration region with a relatively high impurity concentration and a low-concentration region with a relatively low impurity concentration (LDD region) are formed in the source region and the drain region, respectively.

Therefore, a low-concentration source region 41b and a high-concentration source region 41d are formed in the source region, and a low-concentration drain region 41c and a high-concentration drain region 41e are formed in the drain region.

A gate insulating film 42 is formed on the surface of the semiconductor layer 41.

Then, the scanning line 43a is formed on the surface of the gate insulating film 42, and a portion faced to the channel region 41′ is a gate electrode.

A second interlayer insulating film 44 is formed on the surface of the gate insulating film 42 and the scanning line 43a.

Then, the data line 46a is formed on the surface of the second interlayer insulating film 44, and the data line 46a is connected to the high-concentration source region 41d via a connection hole 45 formed on the second interlayer insulating film 44.

A third interlayer insulating film 47 is formed on the surface of the second interlayer insulating film 44 and on the data line 46a.

Then, the pixel electrode 49 is formed on the surface of the third interlayer insulating film 47, and the pixel electrodes 49 are connected to the high-concentration drain region 41d via a connection hole 48 formed in the second interlayer insulating film 44 and the third interlayer insulating film 47.

Moreover, the inorganic oriented film 86 covering the pixel electrode 49 and formed by the manufacturing apparatus 1 is formed on the pixel electrode 49, and can control the orientation of the liquid crystal molecules when applying a non-selective voltage.

In this embodiment, the semiconductor layer 41 is extended to form a first accumulative capacity electrode 41f.

The gate insulating film 42 is extended to form a dielectric film, and the capacity line 43b is arranged on the surface of the dielectric film to form a second accumulative capacity electrode.

The above-mentioned accumulative capacity 57 is constructed by the first accumulative capacity electrode 41f, the second accumulative capacity electrode (capacity line 43b), and the dielectric film (gate insulating film 42).

Furthermore, the first shading film 51 is formed on the surface of the substrate body 80A corresponding to a region forming the TFT element 30.

The first shading film 51 prevents light entering the liquid crystal device from entering into the channel region 41′, low-concentration source region 41b and low-concentration drain region 41c of the semiconductor layer 41, etc.

On the other hand, a second shading film 63 is formed on the surface of the substrate body 90A in the facing substrate 90.

The second shading film 63 prevents light entering the liquid crystal device from entering into the channel region 41′, low-concentration source region 41b and low-concentration drain region 41c of the semiconductor layer 41, etc., and is provided in a region overlapping with the semiconductor layer 41 in the plan view.

A common electrode 61 made of conductors such as ITO, etc. is formed over nearly the entire surface of the facing substrate 90.

Furthermore, an inorganic oriented film 92 formed by the manufacturing apparatus 1 is formed on the surface of the common electrode 61 and can control the orientation of liquid crystal molecules when applying a non-selective voltage.

Then, the liquid crystal layer 50 including of a nematic liquid crystal, etc. is held between the TFT array substrate 80 and the facing substrate 90.

These nematic liquid crystal molecules have a positive dielectric constant anisotropy, horizontally oriented along the substrate when applying a non-selective voltage, and vertically oriented along the direction of electric field when applying a selective voltage.

The nematic liquid crystal molecules have a positive index of refraction constant anisotropy, and a product of its birefringence and thickness of liquid crystal layer (retardation) Δnd becomes, e.g., about 0.40 μm (60° C.).

The direction of orientation control based on the oriented film 86 of the TFT array substrate 80 and the direction of orientation control based on the oriented film 92 of the facing substrate 90 are set to a twisted state of about 90°.

Thereby, the liquid crystal device 60 of this embodiment is operated by a twisted nematic mode.

Polarizing plates 58 and 68 made of a material from doping iodine in polyvinyl alcohol (PVA), etc. are arranged at the outside of the two substrates 80 and 90.

It is desirable that the polarizing plates 58 and 68 be mounted on a support substrate made of a high-thermal conductivity material, such as sapphire glass or quartz, etc., and arranged apart from the liquid crystal device 60.

The polarizing plates 58 and 68 absorb linear polarization in the direction of its absorption axis and have a function of transmitting the linear polarization in the direction of its transmission axis.

The polarizing plate 58 arranged at the TFT array substrate 80 is so arranged so that its transmission axis is in substantially conformity to the direction of orientation control of the oriented film 86, and the polarizing plate 68 arranged at the facing substrate 90 is so arranged that its transmission axis is in substantially conformity to the direction of orientation control of the oriented film 92.

In the liquid crystal device 60, an outside of the facing substrate 90 is faced to the light source.

Only the linear polarization in conformity with the transmission axis of the polarizing plate 68 in the light of the light source transmits through the polarizing plate 68 and enters the liquid crystal device 60.

In the liquid crystal device 60 during the application of a non-selective voltage, the liquid crystal molecules oriented horizontally to the substrate are laminated and arranged in the form of a twisted helix of approximately 90° to the thickness direction of liquid crystal layer 50.

Therefore, the linear polarized light entering the liquid crystal device 60 exits the liquid crystal device 60 with a rotation of approximately 90°.

The linear polarized light transmits through the polarizing plate 58 because it is in conformity with the transmission axis of polarizing plate 58.

Accordingly, a white display is performed in the liquid crystal device 60 during the application of a non-selective voltage (normally white mode).

In the liquid crystal device 60 during the application of a selective voltage, the liquid crystal molecules are oriented vertically to the substrate.

Therefore, the linear polarized light entering the liquid crystal device 60 exits from the liquid crystal device 60 without rotation.

The linear polarized light does not transmit through the polarizing plate 58 because it is perpendicular to the transmission axis of polarizing plate 58.

Accordingly, a black display is performed in the liquid crystal device 60 during the application of a selective voltage.

Here, the inorganic oriented films 86 and 92 formed by the manufacturing apparatus 1 are formed on the inner side of both substrates 80 and 90 as described above.

The inorganic oriented films 86 and 92 are suitably made of silicon oxide such as SiO₂ or SiO as described above, but they may also be made of metal oxides such as Al₂O₃, ZnO, MgO, ITO, etc.

In the liquid crystal device 60 having such inorganic oriented films 86 and 92, since it is possible to prevent the degradation of the film performance of the oriented films 86 and 92 formed by the manufacturing apparatus 1 as described above, the liquid crystal device 60 itself also has desirable qualities.

Furthermore, since productivity of manufacturing the oriented films 86 and 92 can be improved, productivity of manufacturing the liquid crystal device 60 can be also improved.

Projector

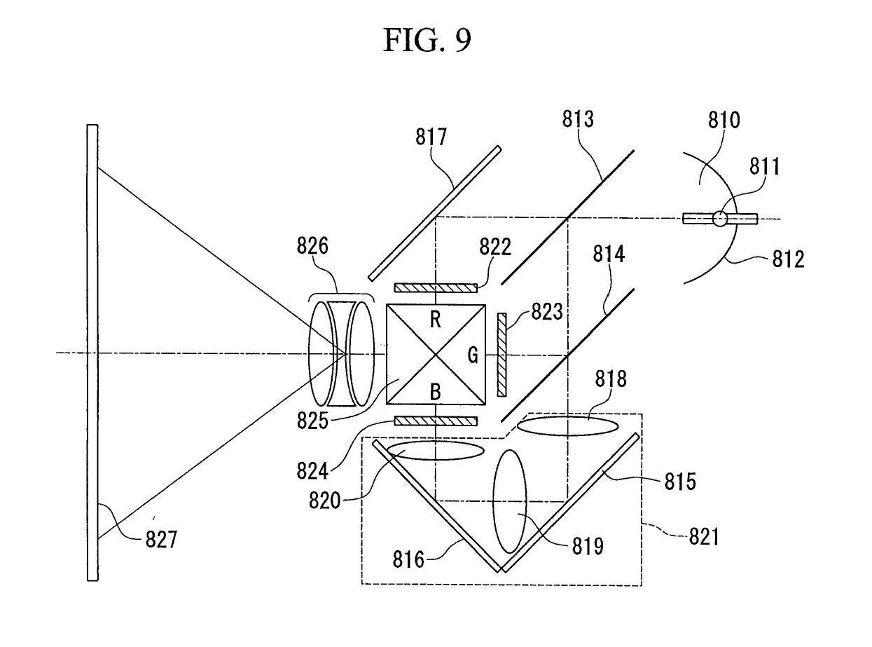

An embodiment of a projector as the electronic device of this invention is described hereinafter with reference to FIG. 9.

FIG. 9 is a schematic block diagram showing the projector.

The projector is provided with the liquid crystal device relating to aforesaid embodiment as a photo-modulation section.

In FIG. 9, reference numeral 810 is a light source, reference numerals 813 and 814 are dichromic minors, reference numerals 815, 816 and 817 are reflecting minors, reference numeral 818 is an entrance lens, reference numeral 819 is a relay lens, reference numeral 829 is an exit lens, reference numerals 822, 823 and 824 are photo-modulation section consisting of the liquid crystal device of invention, reference numeral 825 is a cross dichromic prism, and reference numeral 826 is a projection lens.

The light source 810 includes a lamp 811 such as a metal halide lamp, etc. and a reflector 812 for reflecting light of the lamp.

The dichromic minor 813 transmits red light contained in white light radiated from the light source 810 and reflects blue light and green light.

The transmitted red light is reflected by the reflecting mirror 817 and enters the photo-modulation section 822 for red light.

The green light reflected by the dichromic mirror 813 is reflected by the dichromic minor 814 and enters the photo-modulation section 823 for green light.

The blue light is reflected by the dichromic mirror 813 and transmited through the dichromic mirror 814.

A light-guiding section 821 provided with a relay lens system including the entrance lens 818, relay lens 819 and exit lens 820 is provided to prevent light loss due to a long optical path for blue light.

The blue light enters the photo-modulation section 824 for blue light.

The three color lights modulated by the photo-modulation section 822, 823 and 824 enter the cross dichromatic prism 825.

The cross dichromic prism 825 is formed by pasting four right-angle prisms.

A dielectric multi-layer film for reflecting red light and a dielectric multi-layer film for reflecting blue light are formed in the shape of X and on a boundary face of the prisms.

The three color lights are synthesized by the dielectric multi-layer films to form light expressing a color image.

The synthesized light is projected on a screen 827 by a projection lens 826 including the projection optical system.

The above-mentioned projector is provided with a liquid crystal device as the photo-modulation section.

The liquid crystal device is provided with inorganic oriented films excellent in light resistance and heat resistance as described above.

Therefore, the oriented films do not deteriorate due to strong light radiated from a light source or heat.

The liquid crystal device has desirable qualities and improved productivity, therefore the projector (electronic device) itself also has desirable qualities and improved productivity.

The technical scope of invention is not limited to the above-mentioned embodiment, and embodiments added with various modifications to the above-mentioned embodiment are also included within parameters which do not deviate from the purpose of the invention.

For example, the liquid crystal device provided with TFT as switching elements was described as an example in the embodiment, but this invention is also applied to a liquid crystal device provided with two-terminal elements, such as thin film diodes, etc. as switching elements.

A transmission-type liquid crystal device was described as an example in the embodiment, but it is also possible to apply this invention to a reflection-type liquid crystal device.

A liquid crystal device functioning by TN (Twisted Nematic) mode was described as an example in the embodiment, but it is also possible to apply this invention to a liquid crystal device functioning by VA (Vertical Alignment) mode.

A three-plate type projection display device was described as an example in the embodiment, but it is also possible to apply this invention to a single-plate type projection display device or a direct-view display device.

It is also possible to apply this invention to electronic device other than the projector.

A portable telephone can be given as a specific example thereof.

The portable telephone is provided with a liquid crystal device relating to the above-mentioned embodiments or their modified examples in the display unit. As other electronic device, for example, IC card, video camera, PC computer, head-mount display, moreover, fax device with display function, finder of a digital camera, portable TV, DSP device, PDA, electronic notebook, electric light notice board, display for propagation and announcement, etc. are given.

What is claimed is:

1. A method for manufacturing an oriented film of a liquid crystal device holding a liquid crystal between a pair of substrates facing each other, comprising:
sublimating an oriented film material from an evaporation source;
regulating a sublimating direction in which the oriented film material is sublimated, by a regulating member arranged between the evaporation source and a shielding plate and at a portion closer to the evaporation source than from the shielding plate;
passing the oriented film material through an opening of the shielding plate;
depositing the oriented film material on a substrate by a physical vapor deposition; and
forming the oriented film in an initial evaporating condition which is stable, by moving the shielding plate.

2. A liquid crystal device comprising:
a pair of substrates facing each other;
pixel electrodes formed on one of the pair of substrates;
common electrode formed on the other of the pair of substrates;
switching elements controlling energization of the pixel electrodes;
a liquid crystal layer held between the pixel electrodes and the common electrode, and including liquid crystal molecules; and
an oriented film manufactured by use of the method according to claim 1, formed on a surface of the common electrode and a surface of the pixel electrodes, and controlling orientation of the liquid crystal molecules when applying a non-selective voltage.
